(19) United States
(12) Patent Application Publication
(10) Pub. No.: US 2024/0160806 A1
(43) Pub. Date: May 16, 2024

(54) VIRTUAL TEST ENVIRONMENT FOR A DRIVING ASSISTANCE SYSTEM WITH ROAD USERS MODELLED ON GAME THEORY

(71) Applicant: dSPACE GmbH, Paderborn (DE)

(72) Inventors: Markus FRIEDRICH, Paderborn (DE); Emre Turan SAHIN, Neufahrn bei Freising (DE)

(73) Assignee: dSPACE GmbH, Paderborn (DE)

(21) Appl. No.: 18/406,790

(22) Filed: Jan. 8, 2024

Related U.S. Application Data
(63) Continuation of application No. PCT/EP2021/069002, filed on Jul. 8, 2021.

(51) Int. Cl. G06F 30/20; G06F 11/36

(52) U.S. Cl. CPC G06F 30/20; G06F 11/3664; G06F 11/3684

(57) ABSTRACT

A virtual test environment for a driver assistance system, in which virtual road users are simulated on a game theoretic basis. The virtual test environment is designed to recognize as a game situation at least one predetermined traffic situation in the virtual test environment in which a first road user and a second road user are involved, to designate the first and second road users as a first and second player. A payoff matrix assigned to the game situation is stored in the virtual test environment. The virtual test environment is designed to assign a strategy from a selection of strategies to each of the two players in the game situation, depending on the balance of their respective point account, and to control each of the two players in the game situation in such a manner that they behave in accordance with their respective assigned strategy.

This nonprovisional application is a continuation of International Application No. PCT/EP2021/069002, which was filed on Jul. 8, 2021, and which is herein incorporated by reference.

### BACKGROUND OF THE INVENTION

### Field of the Invention

The invention relates to traffic simulation and virtual testing of driver assistance systems.

### Description of the Background Art

Automobiles with automation level 2 (partially automated driving), which sense their environment through suitable sensor systems such as radar, lidar, or cameras and actively intervene in driving behavior, for example in order to automatically maintain a predefined distance from the preceding vehicle in heavy traffic, to assist in lane keeping, or to perform emergency braking as needed, are already available on the consumer market today. The industry is currently striving for market introduction of automobiles with automation level 3 (highly automated driving). A driver of such a vehicle can take his hands off the steering wheel for relatively long periods while driving and leave steering of his vehicle to the vehicle itself. Vehicles with automation level 5 (autonomous driving) exist as experimental prototypes.

It has been customary for many years in the development of driver assistance systems to make use of virtual test environments, which imitate a use in the field for the driver assistance system. The virtual test environment is a realistic, computer-implemented simulation that includes a virtual test vehicle and a simulated environment of the test vehicle that is modeled on a typical, real application environment of a driver assistance system to be tested and is filled with static or dynamic objects as required. The virtual test environment also includes a logical interface for control of the virtual test vehicle by the driver assistance system. For this purpose, the driver assistance system controls virtual actuators in the virtual test vehicle in the same way that it would control real actuators in a real test vehicle in a field test, and can be tested safely and in a reproducible manner in this way. The virtual test environment can also be designed to feed synthetic sensor data generated by virtual sensors of the virtual test vehicle into sensor data inputs of the driver assistance system. The synthetic sensor data can be, in particular, simulated object lists or synthetic raw data from an imaging sensor, for example from a radar sensor, from a lidar sensor, from an ultrasonic sensor, or from a camera sensor. The test article, which is to say the driver assistance system under test, can be designed in different ways, but normally is at least logically separate from the virtual test environment and is autonomous with respect thereto. The virtual test environment thus includes a generic logical interface for data exchange with the test article, but the test article is not integrated in the virtual test environment and is directly replaceable by another test article. The driver assistance system can be designed as uncompiled program logic, for example as a Simulink model (model in the loop), or as compiled binary code (software in the loop), it can be stored as binary code on a separate processor that is provided for field use in an automobile (processor in the loop), or it can be stored as binary code on an autonomously operating control unit that is provided for field use in an automobile (hardware in the loop).

The complexity of the data that an image-acquiring driver assistance system installed in an automated automobile must process cannot be duplicated in a test setup on a test track. Such systems are tested under realistic, stochastic conditions in order to cover even unforeseen test cases. An obvious approach to this problem, and one that is practiced in the conventional art, is the field test in real road traffic. For adequate validation of a highly automated driver assistance system, however, millions of test kilometers are required in this case to obtain a statistical statement about the safety and reliability of the test article. The reason is that critical situations that bring the assistance system to its limits are rare in reality. The difficult reproducibility of said critical situations as well as the safety aspect are additional problems. A failure of the test article in real road traffic can have grave consequences up to and including the death of persons involved in an accident.

For these reasons, it is desirable to shift the testing of driver assistance systems for automated driving to the virtual world to the greatest degree possible. The concept of randomized, virtual testing was developed for this purpose. Instead of virtually emulating a specific traffic situation in the classic manner, the virtual test vehicle moves in a large virtual test environment, for example in an entire virtual city district or on a complete virtual inter-city highway, together with a multiplicity of virtual road users. The virtual road users move stochastically in the virtual test environment so that the situations the test article will be exposed to cannot yet be predicted at the start of a test drive in the virtual test environment. It is possible in such a virtual test environment to increase the time density of critical situations by influencing the behavior of the virtual road users.

The conventional art still places limits on virtual testing in the field of automated driving, however. Virtual test environments do not yet have the necessary realism that they can, on their own, provide reliable statements regarding a test article's suitability for use in real road traffic. One challenge is the modeling of human-like behavior of the virtual road users. In the ASM Traffic test tool available from the applicant for simulating road users, the behavior of the road users is currently modeled by fixed rules. Road users of the same kind that move in an automated manner thus behave in fundamentally the same way and in a precisely predictable way. Rule violations or dangerous behavior do not occur unless they are intentionally adjusted by controlling a road user. A highly automated driver assistance system that has only been tested under such ideal conditions is not sufficiently validated for use on the road.

For modeling human-like driving behavior, it is also known in the conventional art to control virtual road users through neural networks that are trained to replicate typical human driving behavior. This approach is disclosed in the paper “Artificial neural network modeling of driver handling behavior in a driver-vehicle-environment system” (Y. Lin, P. Tang, and W. J. Zhang, International Journal of Vehicle Design 37(1), 2005), for example. Disadvantages of this approach include the high degree of effort and the large database required for training a neural network, as well its low flexibility after completion of the training. After a successful test drive in the virtual test environment, it may be desirable, for example, to increase the degree of difficulty for the test article by increasing the frequency of rule-breaking behavior or inattentive behavior on the part of virtual road users. The behavior of a trained neural network can no longer be changed easily, however. Apart from this, the behavior of such a neural network may indeed potentially be more diverse and human-like than an explicit set of rules for the behavior of a virtual road user, but it ultimately is just as reproducible and predictable.

In an environment modeled by fixed rules, an increase in the degree of difficulty is indeed possible, namely by re-parameterizing the control of the other road users, but only with a high degree of effort on account of the typically large number of parameters. Moreover, the problem of predictability remains even after re-parameterization.

### SUMMARY OF THE INVENTION

It is therefore an object of the invention to provide a virtual test environment for a driver assistance system in which the driving behavior of the virtual road users is modeled in an unpredictable, human-like, and easily influenced manner.

To attain the object, game-theoretic modeling of the virtual road users is proposed in accordance with the description below.

It is known from the scientific paper “Traffic Games: Modeling Freeway Traffic with Game Theory” (Luis E. Cortes-Berrueco et al., PLOS ONE, 2016) that road traffic can in principle be modeled with game theory. The authors model lane-changing on a multi-laned roadway as a game, and the strategy chosen by a player is dependent upon the player's past experiences.

The invention is a virtual test environment for a driver assistance system. The virtual test environment includes a virtual road, which can also be part of a virtual road network, and a multiplicity of virtual road users. Each of the virtual road users is assigned a point account, which the virtual test environment automatically keeps a record of. The virtual test environment is designed to recognize as a game situation at least one predetermined traffic situation in the virtual test environment in which a first road user with a first point account and a second road user with a second point account are involved, to designate the first road user as a first player in the game situation, and to designate the second road user as a second player in the game situation.

A game situation can be understood as a predetermined traffic situation that, when it occurs, is modeled as a game within the meaning of the technical term from game theory, i.e., as a situation with at least two participants who are both seeking to advance their own interests in the situation and have different strategies to choose from to do so, without knowing in advance what strategy the other respective participant will employ. The following are examples of traffic situations that are recognizable as a game situation: a turning situation, in which the first road user seeks to turn into a road on which the second road user, who has right of way over the first road user, is traveling; a merging situation, in which the first road user seeks to change to a lane being used by the second road user; a car-following situation, in which the first road user is driving behind the second road user in a lane and seeks to pass the second road user; and a crossing situation, in which the first road user seeks to cross a road on which the second road user, who has right of way over the first road user, is traveling.

Moreover, a payoff matrix that is assigned to the game situation is stored in the virtual test environment. A payoff matrix can be understood as a table from which a payoff value, i.e., a point gain or point loss after the conclusion of the game situation, that is dependent on the course of the game situation can be read for both the first player and the second player. In accordance with the technical term “payoff matrix” used in game theory, it is preferred in this case for the course of the game to be dependent on the strategies chosen by the first player and the second player, which is to say that the payoff value for both the first player and the second player is dependent upon what strategy the first player has chosen and what strategy the second player has chosen for the game situation.

In addition, a selection of strategies for a behavior in the game situation is stored in the virtual test environment. The virtual test environment is designed to assign the first player in the game situation a first strategy from the selection of strategies and to assign the second player in the game situation a second strategy from the selection of strategies, wherein the first strategy and the second strategy can be identical or different. In this case, the selection of the first strategy is dependent on the balance of the first point account and the selection of the second strategy is dependent on the balance of the second point account.

The virtual test environment is designed to control the first player in such a manner that the first player behaves in accordance with the first strategy in the game situation, and to control the second player in such a manner that the second player behaves in accordance with the second strategy in the game situation. The virtual test environment is additionally designed to read out a first payoff value from the payoff matrix provided for the course of the game situation for the first player and apply it to the first point account, and to read out a second payoff value from the payoff matrix provided for the course of the game situation for the second player and apply it to the second point account.

Thus, both players generally leave the game situation with a changed balance in their respective point account, wherein the balance in the point account influences the selection of a player's strategy. The strategy selected by a virtual road user is therefore dependent on the individual experiences that user has gained in past games. For example, if the virtual test environment is set up such that a high balance in the point account has a positive connotation because a successful course of a game situation for a given player is rewarded with a high positive payoff value, then a high balance in his point account can cause a player to choose an aggressive and thus incautious strategy, whereas a low balance causes the player to choose a cautious, cooperative strategy. In this example, a road user who has a high balance in his point account would be a road user who has had few bad experiences in road traffic in the recent past, and therefore tends toward an incautious driving style. It is to be expected that an equilibrium of strategies will establish itself in the virtual test environment among the virtual road users after a certain settling time. The strategies that are available in the selection will then be found among the virtual road users in a specific ratio that can be influenced by the parameterization of the virtual test environment. However, which strategy a given road user will pursue in a game situation, for example whether he will behave cooperatively or aggressively, is not predictable.

A point account can be understood in this context as an abstract measure of a satisfaction of the virtual road user to whom the point account is assigned, wherein a course of a game situation that is satisfactory for the road user is rewarded with a positive payoff value for the road user. A point account can be viewed in a figurative sense as an abstract time account, wherein a high balance in the point account implies a high time saving, a course of a game situation that saves time for a player is rewarded with a positive payoff value for the road user, and a course of a game situation that is time-consuming for the player is punished with a negative payoff value. In this context, the payoff value need not by any means be based on an objective time measurement, but instead can also reflect a subjectively perceived saving of time or a subjectively perceived loss of time for the player.

In addition to the multiplicity of virtual road users, the virtual test environment also can include a virtual test vehicle. The virtual test vehicle can be distinguished from the virtual road users in that it is not controlled or is not controlled solely by the virtual test environment, but instead is controlled at least at times by an entity that is located logically outside the virtual test environment. To this end, the virtual test environment includes a logical interface for control of the virtual test vehicle. By means of the logical interface, the virtual test vehicle can be controlled by a driver assistance system under test. This in no way precludes the virtual test environment from also controlling the vehicle in addition to the driver assistance system. Especially when the driver assistance system is configured to control the virtual test vehicle only temporarily or in specific traffic situations, the virtual test environment can control the virtual test vehicle analogously to the way a real driver would control a real vehicle equipped with the driver assistance system, wherein control signals of the test system normally take precedence over control signals from the virtual test environment. If, for example, the driver assistance system is an emergency braking assistance system, the driver assistance system can brake the virtual test vehicle without the virtual test environment having initiated a braking of the virtual test vehicle.

The virtual test vehicle can become a player in a game situation in the same way as a virtual road user, wherein the control of the virtual test vehicle also takes place unchanged through the logical interface even in the game situation provided that the driver assistance system intervenes in the control of the virtual test vehicle. The virtual road user that is the opponent of the virtual test vehicle in the game situation behaves toward the virtual test vehicle in the game situation as though the virtual test vehicle were one of the virtual road users. It is therefore testable in the game situation whether the driver assistance system satisfactorily handles the game situation or the behavior of the opponent in the game situation.

Preferably, the point accounts are not accessible to the driver assistance system.

The control of the virtual test vehicle by the virtual test environment can be implemented in many different ways. The virtual test environment may treat the virtual test vehicle like a virtual road user, in particular keeps a point account of the virtual test vehicle and assigns a strategy to the virtual test vehicle in a game situation in the same manner as for the virtual road users. The virtual test environment can include an exclusive agent for controlling the virtual test vehicle so that its control is independent of the control of the virtual road users and can follow separate rules. In yet another example, no control of the virtual test vehicle may be carried out by the virtual test environment, and the control of the virtual test vehicle takes place entirely and permanently through the logical interface. The virtual test vehicle can, for example, be controlled by a human test driver in a driving simulator or by a driver assistance system that is designed for autonomous control of a vehicle.

Finally, the virtual test environment also includes a programming interface by means of which the payoff matrix and/or an adjustment value for the point accounts that influences the assignment of the first strategy and the second strategy can be changed. The adjustment value can be, for example, a global threshold value for the point accounts that, when it is exceeded in a point account, causes the virtual test environment to change the strategy of the virtual road user to whom the point account is assigned. The virtual test environment can be designed to randomly select the first strategy and the second strategy, wherein the probability for the selection of a given strategy in each case is given by a formula in which the balance in the point account and the adjustment value are offset against one another so that the probability of assigning a given strategy to the first player or the second player can be influenced by means of the adjustment value.

Accordingly, it is possible to adjust a degree of difficulty of the virtual test environment for the driver assistance system with the aid of the programming interface by influencing the assignment of strategies to virtual road users in a game situation by changing a few parameters, in particular a single parameter. In particular, the proportion of road users in the virtual test environment who behave aggressively or contrary to the rules can be changed by means of the programming interface. Changing the payoff matrix or the adjustment value causes the equilibrium of the strategies assigned in the virtual test environment to change, and the proportions of the strategies stored in the selection settle into their new equilibrium values after a transient settling phase.

Influencing the assignment of strategies also makes it possible to easily adjust the virtual test system in order to emulate a locally typical traffic pattern of a geographic location with the virtual road users. Such an adjustment can be based, for example, on an analysis of the local traffic of the geographic location, by which means it is determined what strategies can be observed with what relative frequency in the local traffic. The virtual test environment can then be adjusted in such a manner that it represents the same spectrum of strategies with the same relative frequency as the local traffic of the geographic location.

The invention also relates to a computer-implemented method for testing a driver assistance system in the virtual test environment, comprising the steps: Configuration of the driver assistance system to control a virtual test vehicle in the virtual test environment; Configuration of the virtual test environment to feed synthetic sensor data into at least one sensor data input of the driver assistance system; Performance of a first test drive of the driver assistance system in the virtual test environment; Increasing a degree of difficulty of the virtual test environment after conclusion of the first test drive by changing the payoff matrix or an adjustment value for the point accounts that influences the assignment of the first strategy and the second strategy in such a manner that the probability that an aggressive strategy is assigned to the first player or the second player is increased after the change; and Performance of a second test drive of the driver assistance system in the virtual test environment after increasing the degree of difficulty.

The virtual test environment can be designed to read in a user-defined value at the programming interface, from which value a target proportion of aggressive road users in the virtual test environment can be derived. The user-defined value can be an explicit target value in percent or another value to which the virtual test environment assigns, for example by means of a formula or a tabular assignment, a percent target value, for example a degree of difficulty selected by a user. The virtual test environment in this example can include a regulating algorithm in order to adjust the probability that an aggressive strategy is assigned to the first player or the second player to the target proportion by means of an iterative change in the payoff matrix or the adjustment value.

For the purpose of resource-saving simulation of the virtual test environment, the virtual test environment can be designed to not populate the entire virtual test environment with virtual road users, but instead only a fraction of the virtual test environment, which is defined by a mobile reference environment of the virtual test vehicle whose dimensions are smaller than the dimensions of the virtual test environment. The virtual test environment constantly can generate new virtual road users at the boundaries of the reference environment and adds the new virtual road users to the virtual test environment, and the virtual test environment constantly causes virtual road users to vanish at the boundaries of the reference environment and removes vanished virtual road users from the virtual test environment. If the virtual test vehicle includes a virtual imaging sensor, the boundaries of the mobile reference environment preferably are located outside a field of view of the imaging sensor.

The virtual test environment can be designed to store the balance of the point account of a removed virtual road user when removing the virtual road user. At a later time, when adding a new virtual road user, the virtual traffic environment transfers the stored balance of the point account to the point account of the added virtual road user. Each road user newly added to the virtual test environment accordingly inherits the point account of an earlier virtual road user removed from the virtual test environment. Thus, the virtual test environment may appear from the perspective of the driver assistance system to be a richly populated environment with a great multiplicity of road users, while the virtual test environment need only manage a reasonable number of potential players. Preferably, the number of players is of course sufficiently large to confront the driver assistance system with different game strategies in the desired relative proportions to one another.

The behavior of an arbitrary virtual road user in the simulated road traffic of the virtual test environment can be dependent on the balance of the point account of the respective road user even outside of game situations. The virtual test environment is designed to end the game situation again, i.e., to withdraw the status of first player from the first road user after conclusion of the game situation and to withdraw the status of second player from the second road user after conclusion of the game situation. After withdrawing the status of first player, the virtual test environment can control the first road user in such a manner that the behavior of the first road user is dependent on the balance of the first point account, however. Accordingly, after withdrawing the status of second player, the virtual test environment can also control the second road user in such a manner that the behavior of the second road user is dependent on the balance of the second point account.

The balance in the point account of a given virtual road user can determine how the road user in question behaves at traffic lights or stop signs or the extent to which he observes speed limits, for example.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a test-stand setup for a driver assistance system with a virtual test environment;

FIG. 2 shows a schematic detail from the virtual test environment;

FIG. 3 shows a first exemplary game situation;

FIG. 4 shows the first exemplary game situation in an example of the virtual test environment;

FIG. 5 shows a second exemplary game situation;

FIG. 6 shows a third exemplary game situation;

FIG. 7 shows a fourth exemplary game situation; and

FIG. 8 shows the virtual test environment with a mobile reference environment of the virtual test vehicle, at the boundaries of which the virtual test environment adds and removes virtual road users.

### DETAILED DESCRIPTION

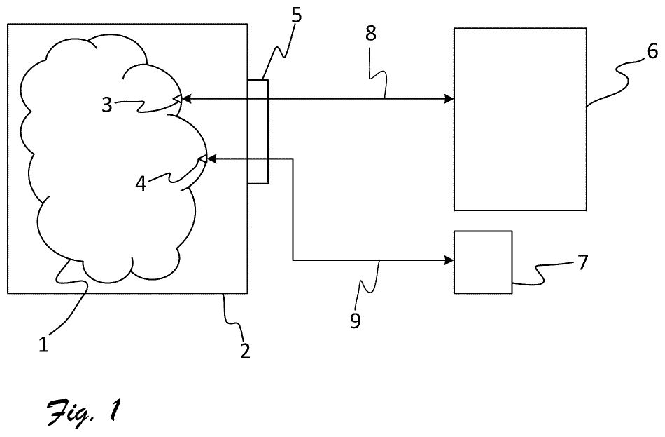

The illustration in FIG. 1 shows a schematic representation of a test-stand setup for a driver assistance system 6. The setup includes a simulation computer 2 with an I/O interface 5 for data exchange with a peripheral of the simulation computer 2. A virtual test environment 1 is programmed on the simulation computer 2. A driver assistance system 6 is integrated in the setup as a test article. The driver assistance system 6 is configured for data exchange with the simulation computer 2 by means of a first data connection 8 between the I/O interface 5 and the driver assistance system 6 in order to control a virtual test vehicle VE in the virtual test environment 1 through a logical interface 3 of the virtual test environment 1 and to read in synthetic sensor signals from virtual sensors of the virtual test vehicle VE. The driver assistance system 6 is thus situated in a closed control loop with the virtual test vehicle VE, and the simulation computer 2 is designed to execute the virtual test environment 1 in hard real time in order to realistically simulate the virtual test vehicle VE as well as an environment of the virtual test vehicle VE for the driver assistance system 6.

An operating terminal 7 designed as an ordinary commercial personal computer (PC) is configured for data exchange with the simulation computer 2 by means of a second data connection 9 in order to parameterize the virtual test environment 1 as specified by an operator of the test-stand setup through a programming interface 4 of the virtual test environment 1.

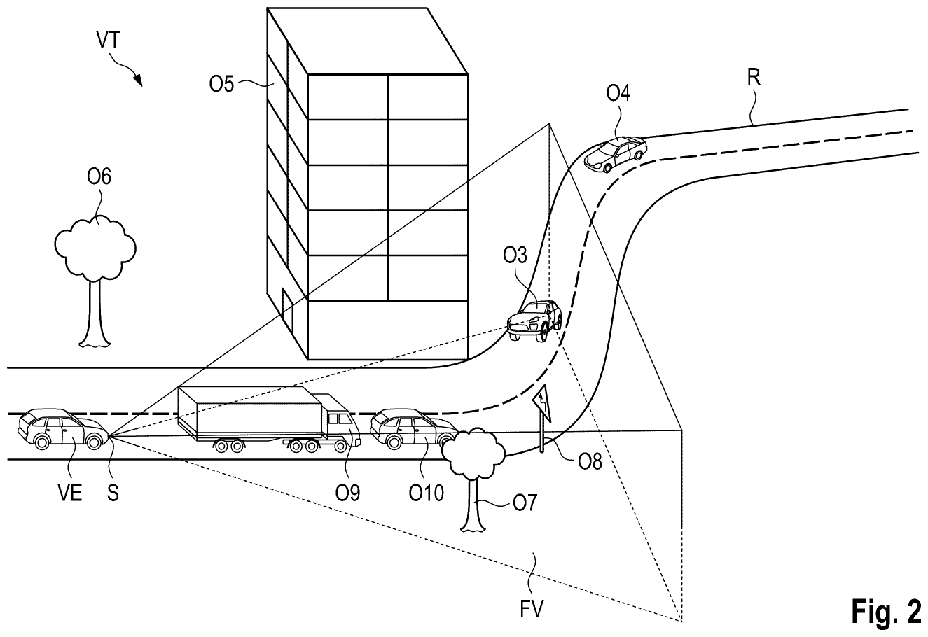

In a schematic representation, the illustration in FIG. 2 shows an exemplary detail from the virtual test environment 1. The virtual test environment 1 includes a rendering engine. The virtual test environment is designed to synthesize a photorealistic, two-dimensional image from a 3D model VT set up in the virtual test environment 1 in hard real time and from an arbitrary, changeable camera perspective. Such rendering engines are available from the gaming industry, in particular. Examples include Unreal Engine, Cry Engine, and Unity Engine. The 3D model VT includes a multiplicity of static and dynamic objects O3 . . . O10, which as a whole emulate a typical application environment of the driver assistance system 6. Depicted by way of example as static objects are vegetation, buildings, and traffic signs. Depicted by way of example as dynamic objects are automobiles and trucks. Other possible examples of dynamic objects are pedestrians, bicyclists, motorcyclists, athletes, and buses. Virtual road users can be understood as selected dynamic objects that are configured to change their absolute location coordinates within the 3D model VT and whose counterparts in the real world are capable of rules-compliant participation in road traffic. Possible virtual road users are, in particular, all examples of dynamic objects listed above. The virtual test environment 1 includes agents for controlling the virtual road users.

The virtual test environment 1 additionally includes the virtual test vehicle VE, which travels on a virtual road R in the 3D model VT. As compared with the virtual road users, the virtual test vehicle VE is distinguished by the fact that it includes virtual actuators and virtual sensors S. The virtual actuators are configured to read in control signals from the driver assistance system 6 and to simulate an actuator effect on the virtual test vehicle VE in response to the control signals. The virtual sensors are configured to generate synthetic sensor data representing the 3D model from the perspective view of a sensor S mounted on the virtual test vehicle VE. The synthetic sensor data can emulate raw data from an imaging sensor, for example from a camera sensor, from a radar sensor, from a lidar sensor, or from an ultrasonic sensor. The synthetic sensor data can also be implemented as an object list that lists virtual road users located in a sensor field of view FV of the virtual test vehicle VE.

The driver assistance system 6 is configured to read out the synthetic sensor data from at least one simulated sensor S, to process it, and to take it into account in the generation of control signals. The driver assistance system 6 thus interacts with the virtual test vehicle VE and the virtual environment thereof in the same way as the driver assistance system 6 would interact with a real vehicle in which it is installed, and the environment thereof.

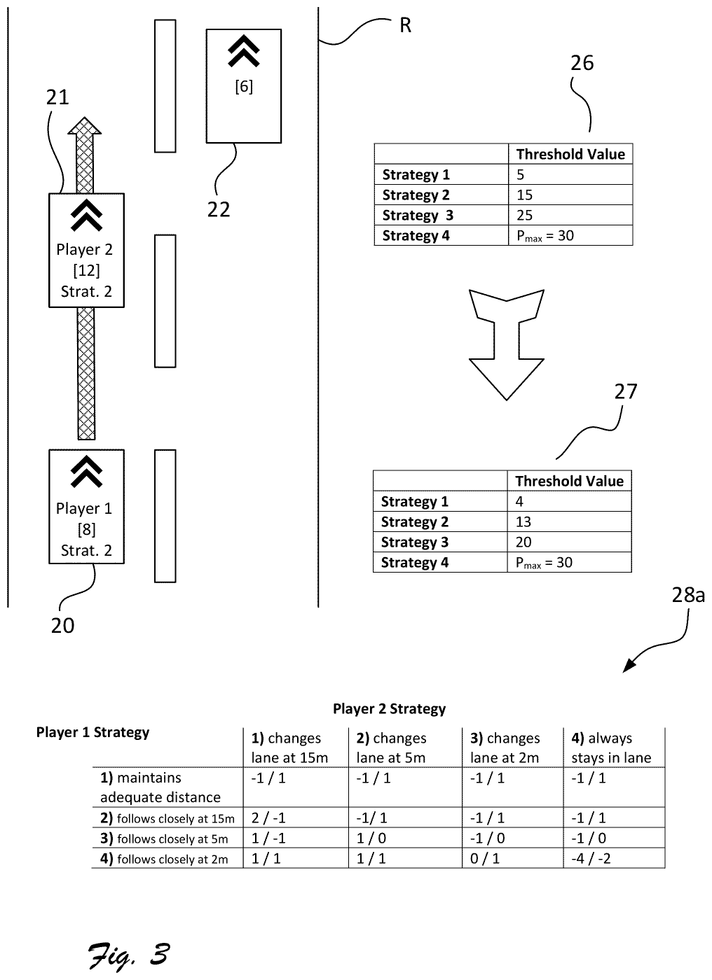

The virtual test environment 1 is designed to monitor variable parameters of the virtual test vehicle VE and of the virtual road users and to recognize predetermined traffic situations as game situations on the basis of the variable parameters. As a first example of a traffic situation that can be recognized as a game situation, the illustration in FIG. 3 shows a car-following situation. On the virtual road R, a first road user 20 is driving behind a second road user 21 in the left lane of two lanes. The second road user 21 is in the process of passing a third road user 22. The second road user 21 is traveling more slowly than a target speed of the first road user 20, which is to say that the first road user 20 seeks to pass the second road user 21.

The virtual test environment 1 automatically recognizes the traffic situation as a game situation, “car-following game,” that is predefined in the virtual test environment 1, and designates the first road user 20 as the first player (player 1) and the second road user 21 as the second player (player 2). The predefined parameter constellation in the virtual test environment 1, on the basis of which the virtual test environment 1 recognizes a traffic situation as a car-following game, is: the first road user 20 and the second road user 21 are in the same lane; the second road user 21 is ahead of the first road user 20; the target speed of the first road user 20 is higher than the actual speed of the second road user 21; and the first road user 20 is in the outermost lane or it is impossible for the first road user to change to a next outer lane.

A coordinate axis running parallel to the road R is defined in the virtual test environment 1, and a position on the coordinate axis is assigned to each road user located on the road R. As a result, it is possible to directly check whether the second road user 21 is ahead of the first road user 20. In addition, the lanes of the road R are numbered consecutively in the virtual test environment 1, and a lane number is assigned to each road user located on the road R. As a result, it is possible to directly check whether the first road user 20 and the second road user 21 are located in the same lane.

The virtual test environment 1 keeps a point account for each virtual road user 20, 21, 22, the respective balance of which is given in square brackets in the illustrations and is a result of a history of the respective road user in the course of earlier games. The first player 20 is assigned a first point account whose current balance is eight points. The second player 21 is assigned a second point account whose current balance is twelve points.

In the course of the game, each player in the car-following game can pursue one of four strategies from a selection of strategies. For the first player 20, the selection includes a cooperative strategy (strategy 1), which includes maintaining a safe distance S from the second player 21 until the second player 21 independently clears the lane. The three remaining strategies are aggressive strategies that have the first player 20 travel closely behind (“tailgate”) the second player 21 in order to force the second player 21 to clear the lane. Depending on the selected strategy, the second player 20 drives to a following distance of 15 m (strategy 2), 5 m (strategy 3), or 2 m (strategy 4) from the first player 21.

For the second player 21, the selection likewise includes four strategies: A cooperative strategy (strategy 1), which has the second player 21 clear the lane as soon as the first player approaches within 15 m. Thus, in this strategy the second player 21 yields as soon as the first player 20 is aggressive in even the mildest form. The remaining strategies are aggressive strategies, in which the second player 21 attempts to stay in his lane while accepting the risk of an accident. Depending on strategy, he does not change lanes until the first player approaches within 5 m (strategy 2) or within 2 m (strategy 3), or he does not prematurely clear the lane under any circumstances (strategy 4).

What strategy the virtual test environment 1 assigns to a player is dependent on the player's point account balance P. Stored in the virtual test environment is a threshold table 26, in which upper threshold values for the individual strategies are stored as adjustment values for the point accounts. In the depicted example, a player is assigned the strategy 1 when the balance in his point account is five or less. The strategy 2 is assigned to a player when the balance in his point account is within the interval of six to fifteen points, and so on. The threshold value “30” for the strategy 4 is simultaneously a maximum value Pₘₐₓ for the point account balance of a player. The minimum value of the point account balance is zero. A negative account balance is not possible.

The virtual test environment 1 assigns the strategy 2 to both the first player 20 and the second player 21 in the game situation in accordance with the balances in their point accounts, and controls both players in such a manner that they behave in accordance with their assigned strategy in the game situation. The first player 20 accordingly drives to within a 15 m distance from the second player 21. However, since the strategy of the second player 21 provides for not clearing the lane until the first player 20 drives to within 5 m, the second player 21 stays in the lane and duly completes the passing maneuver.

Stored in the virtual test environment 1 is a first payoff matrix 28a assigned to the car-following game, in which a first payoff value for the first player 20 and a second payoff value for the second player 21 are stored in each entry, dependent on the course of the car-following game. Specifically, the payoff values are dependent on the first strategy and the second strategy. In each case, the first payoff value is given before the slash, and the second payoff value after the slash. Payoff values can be positive or negative. The virtual test environment 1 reads the first payoff value out from the first payoff matrix 28a and applies it to the first point account of the first player 20, and the virtual test environment 1 reads the second payoff value out from the first payoff matrix 28a and applies it to the second point account of the second player 21. Both players have pursued strategy 2 in the game situation. Accordingly, the virtual test environment 1 deducts one point from the first point account for the first player 20, and the balance in the point account of the first player 20 drops from eight to seven. For the second player 21, the virtual test environment 1 credits one point to the second point account, and the balance of the second point account increases from twelve to thirteen. The virtual test environment 1 concludes the game situation and once again controls the first road user 20 and the second road user 21 independently of one another through the virtual test environment 1. The new balances of the first and second point accounts are retained after conclusion of the game situation until the first road user 20 and/or the second road user 21 are again designated as players in a game situation.

The point system in the virtual test environment 1 shown in the figures is designed such that players behave more aggressively the higher the balance in their respective point accounts is, wherein a successful assertion of their own interests with little self-endangerment in a game situation is rewarded with positive credits to the point account. A high point account balance of a virtual road user 20, 21 implies that the virtual road user has accumulated only few negative experiences in game situations in the recent past and therefore behaves incautiously. In the example outlined above, the first player 20 has placed himself in danger, if only slightly, and has not derived any benefit in exchange. (His strategy, forcing the second player 21 to prematurely clear the lane, did not work out.) Accordingly, he gets a small point deduction of one point from his point account. The second player 21 did assert his interests while accepting a slight risk of accident, and avoided a loss of time by not terminating the passing process, and receives a credit to his point account in reward. An encounter between two players who are both pursuing the extreme strategy 4, on the other hand, is punished with a point deduction for both players. For the first player 20, the point deduction of four points is especially high because he has incurred a high risk of accident and has not derived any benefit in exchange. For the second player 21, the point deduction is smaller. The second player 21 has also incurred a high risk of accident through his behavior but, in contrast to the first player 20, did derive a benefit due to the avoided lane change.

The behavior of a virtual road user 20, 21, 22 in the simulated road traffic of the virtual test environment 1 can be dependent on the balance in the point account of the respective road user even outside of game situations, which is to say when the respective road user is not designated a player in a game situation at the moment. For example, a road user who tends toward aggressive strategies in game situations on the basis of the balance in his point account can exhibit an aggressive or incautious behavior pattern outside of game situations, as well.

For example, a distance from a traffic signal that is dependent on the balance in the point account and within which the road user accelerates when the traffic signal changes from green to yellow can be stored for a road user designed as an automobile. The balance in the point account can determine the behavior of the road user at a stop sign, for example in such a manner that a road user whose point account balance corresponds to strategy 1 brings his vehicle to a standstill at a stop sign in compliance with the rules, a road user whose point account balance corresponds to strategy 2 or 3 rolls past the stop sign at a reduced speed, and a road user whose point account balance corresponds to strategy 4 ignores the stop sign. The balance in the point account can determine the extent to which the road user observes speed limits, for example in such a manner that a road user whose point account balance corresponds to strategy 1 observes maximum speed limits, while road users whose point account balances correspond to strategies 2, 3, or 4 exceed maximum speed limits to an increasing degree.

The first payoff value and the second payoff value need not by any means be determined solely by the first payoff matrix 28a, but can alternatively or additionally be subject to other rules as well. For example, the virtual test environment 1 can be designed to set the balances of both the first point account and the second point account to zero or to reduce the balances by a large amount when a rear-end collision of the first player 20 with the second player 21 actually occurs during the course of the game situation. For the purpose of recognizing an accident, the virtual test environment 1 can be equipped with an algorithm for collision detection in order to detect an intersection of a bounding box of the first player 20 with a bounding box of the second player 21. Analogously, alternative or additional rules for payoff values that are not dependent solely on the strategies assigned in the game situation in question can also be stored for different game situations, for example those depicted in subsequent figures. Moreover, the payoff values need not necessarily be stored as constant values, but can also be stored as variable values as a function of static or variable parameters of the virtual test environment.

The virtual test environment 1 can also assign the role of the first player 20 as well as the role of the second player 21 to the virtual test vehicle VE—in the car-following game as well as in different game situations, such as those depicted in the subsequent figures. In this way, the driver assistance system 6 is confronted with a multiplicity of game situations and different strategies of virtual road users 20, 21 during a virtual test drive in the virtual test environment 1. When the virtual test vehicle VE is a player in a game situation, however, the driver assistance system 6 can control the virtual test vehicle VE in the game situation as well, and in this way influence the course of the game situation.

Such a confrontation can also occur indirectly, without the virtual test vehicle VE being designated a player. For example, the virtual test vehicle VE can be forced into an emergency-braking maneuver or an evasive maneuver because the second player 21 in a car-following game, in which the virtual test vehicle VE is not involved as a player, unexpectedly changes lanes. In another example, the virtual test vehicle VE is forced into an emergency-braking maneuver or an evasive maneuver without being involved in the car-following game as a player because the car-following game causes a rear-end collision of the first player 20 with the second player 21. This is why the virtual test environment 1 can be designed to simulate accidents in a detailed and physically realistic manner, for example taking into account the action of force of a collision, secondary collisions, and evasive or braking maneuvers of other virtual road users.

After a successfully completed test drive of the virtual test vehicle VE in the virtual test environment 1, a degree of difficulty of the virtual test environment can be increased by means of operating software stored on the operating terminal 7. For this purpose, the threshold table 26 is converted into a modified threshold table 27, in which a lower threshold value than in the original threshold table 26 is stored for each strategy.

It is thus more probable with the modified threshold table 27 that a given player in a game situation pursues an aggressive strategy, and the driver assistance system 6 is confronted with challenging situations more frequently. The threshold values can be changed directly by means of the operating software. The threshold table 26 and the modified threshold table 27 can be predefined, and different degrees of difficulty that are selectable by means of the operating software are assigned to the virtual test environment 1. In addition to the threshold table 26 or instead of the threshold table 26, the first payoff matrix 28a can be converted into a modified payoff matrix that rewards players more strongly with positive payoff values than the original first payoff matrix 28a or that, expressed more generally, tempts the players more strongly to an aggressive strategy through its payoff values than the original, first payoff matrix 28a.

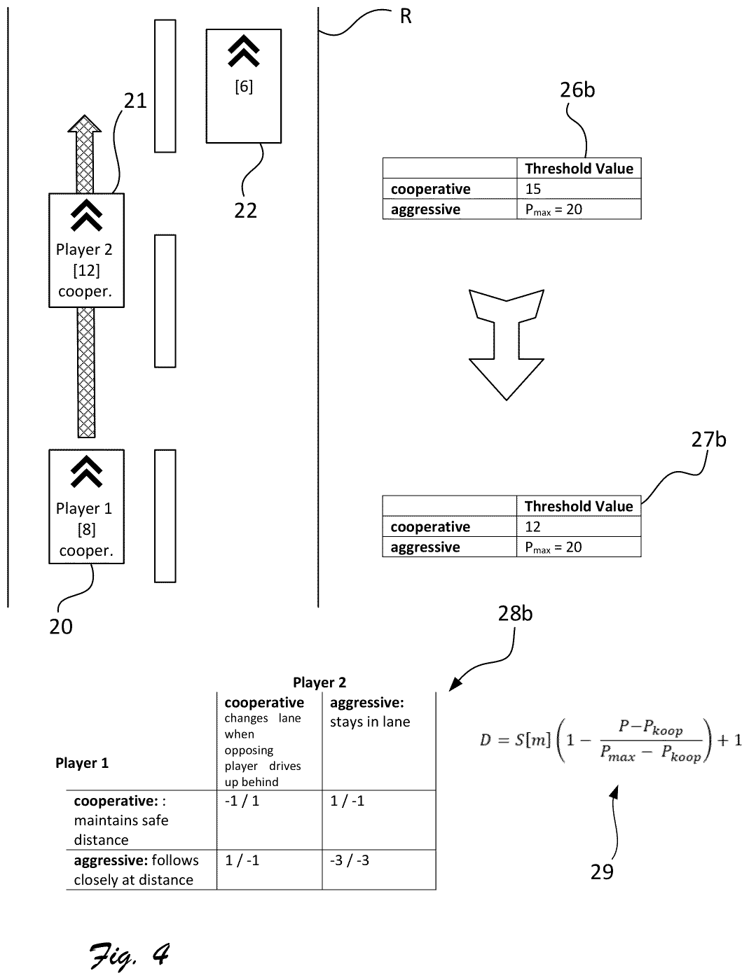

The illustration in FIG. 4 shows an example of the car-following game with a second payoff matrix 28b, in which the selection of strategies for both players includes only two strategies, one cooperative and one aggressive strategy for each. If the first player 20 is assigned the cooperative strategy, he maintains a predefined safe distance S, which can be, for example, two driving seconds of the first player 20. If the first player 20 is assigned the aggressive strategy, the first player 20 drives up to a distance D from the second player 21 in order to force the second player 21 to clear the lane. If the second player 21 is assigned the cooperative strategy, he only stays in the lane if the first player 20 is also behaving cooperatively, and clears the lane when the first player 20 drives up. If the second player 21 is assigned the aggressive strategy, he does not clear the lane prematurely under any circumstances. In order to introduce variance into the game situations, the distance D in each car-following game is determined by a formula 29 that has the first player 20 drive up closer to the second player 21 the higher the balance in the point account of the first player 20 is. In the formula 29, S is the safe distance in meters, P is the point account balance of the first player 20, Pₘₐₓ is the maximum value of the point accounts, and Pₖₒₒₚ is the threshold value of the cooperative strategy stored in the threshold table 26 or in the modified threshold table 27.

Further exemplary traffic situations that can be recognized as game situations are discussed below. The virtual test environment can be designed to recognize several different traffic situations as different game situations, wherein separate selections of strategies that are assigned to the respective game situation are stored for each game situation in the virtual test environment 1. Furthermore, a separate payoff matrix assigned to the respective game situation is stored for each game situation in the virtual test environment 1. The steps previously performed for the car-following game occur analogously for all other game situations. The virtual test environment can be designed to maintain multiple point accounts in parallel for each virtual road user, including, in particular, for the virtual test vehicle VE, wherein each point account of a virtual road user is assigned to a game situation. The virtual test environment 1 can also be designed to maintain only one point account, which is not exclusively assigned to any game situation, for each virtual road user, including, in particular, the virtual test vehicle VE. It is possible for a separate threshold table 26 assigned to the respective game situation to be stored for each game situation in the virtual test environment 1. It is also possible for only one threshold table, which is not exclusively assigned to any game situation, to be stored in the virtual test environment. The conversion of the threshold table 26 into a modified threshold table 27 described above with reference to FIG. 3 as well as the conversion of the payoff matrix 28a into a modified payoff matrix described above with reference to FIG. 3 can be performed analogously for other game situations other than the car-following game as well. Analogously to the formula shown in FIG. 4, distance specifications used in the payoff matrices described below can alternatively also be determined using a formula.

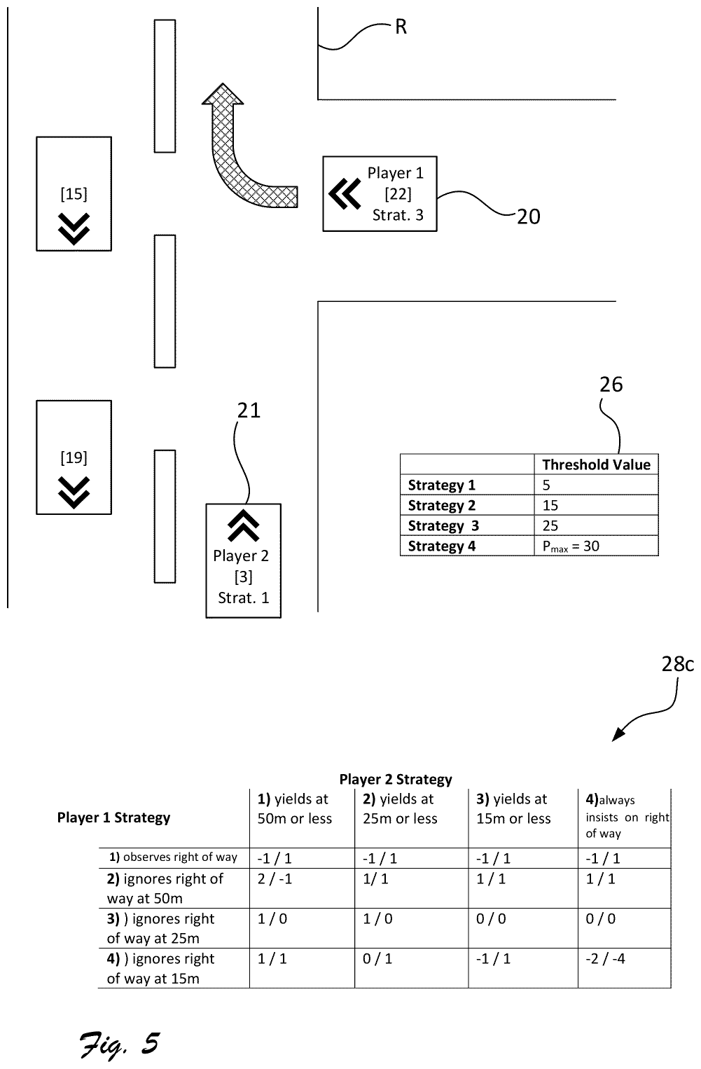

The illustration in FIG. 5 shows a turning situation as a second example of a game situation. The first road user 20 seeks to turn into the road R, in which the second road user 21, who has right of way over the first road user 21, is approaching. The virtual test environment 1 recognizes the traffic situation as a “right-of-way game” game situation, and designates the first road user 20 as the first player and the second road user 21 as the second player. The predefined parameter constellation on the basis of which the virtual test environment 1 recognizes a traffic situation as a right-of-way game is: on the coordinate axis running parallel to the road R, the first road user 20 is located at a point that the second road user 21 is moving toward; the distance of the first road user 20 from the second road user on the same axis is below a certain threshold value, for example 150m; the first road user 20 is at the verge of the road R on which the second road user 21 is traveling, but is not yet located on the said road R; there are no other road users between the first road user 20 and the second road user 21 in the lane in which the second road user is traveling; and the target lane of the first road user 20 is the lane in which the second road user 21 is traveling.

As in the car-following game, the selection of strategies includes four strategies for each player, one cooperative and three aggressive for each. The cooperative strategy of the first player 20 includes yielding the right of way to the second player 21, which is to say not turning into the road R until after the second player 21 has passed the first player 20 (strategy 1). With an aggressive strategy, the first player 20 ignores the right of way of the second player 21, which is to say turns into the road R before the second player 21 has passed the first player 20. In doing so, the first player 20 does not start until the second player 21 has approached the first player 20 to within a certain distance, namely to within 50 m (strategy 2), 25 m (strategy 3), or 15 m (strategy 4).

The cooperative strategy (strategy 1) of the second player 21 includes reducing his speed when the first player 20 ignores his right of way at a distance of 50 m or less in order to give the right of way to the first player 20 and allow the first player 20 to merge safely into the lane in which the second player is traveling. With an aggressive strategy, the second player 21 reduces his speed depending on the selected strategy: only when the first player 20 starts at 25 m or less (strategy 2), at 15 m or less (strategy 3), or under no circumstances (strategy 4). In other words, when the second player 21 is assigned the strategy 4, he does not perform a braking maneuver under any circumstances, and maintains his speed regardless of how little margin the first player 20 leaves when ignoring his right of way.

The threshold table 26 is, by way of example, the same threshold table that is also used for the car-following game. Alternatively, a separate threshold table assigned to the respective game situation can of course also be stored for each game situation. The balance in the point account of the first player 20 is twenty-two points. The virtual test environment 1 therefore assigns the first player 20 strategy 3 as the first strategy. The balance in the point account of the second player is three points. The virtual test environment therefore assigns the second player strategy 1 as the second strategy. The virtual test environment 1 thus controls the two players in such a manner that the first player 20 allows the second player 21 to approach to a distance of 25 m and then starts up in order to ignore the second player's right of way, and the second player 21 performs a braking maneuver in order to allow the first player 20 to go. After this, the virtual test environment 1 consults a third payoff matrix 28c assigned to the right-of-way game, credits the first player 20 one point to his point account, leaves the point account of the second player 21 unchanged, and concludes the game situation.

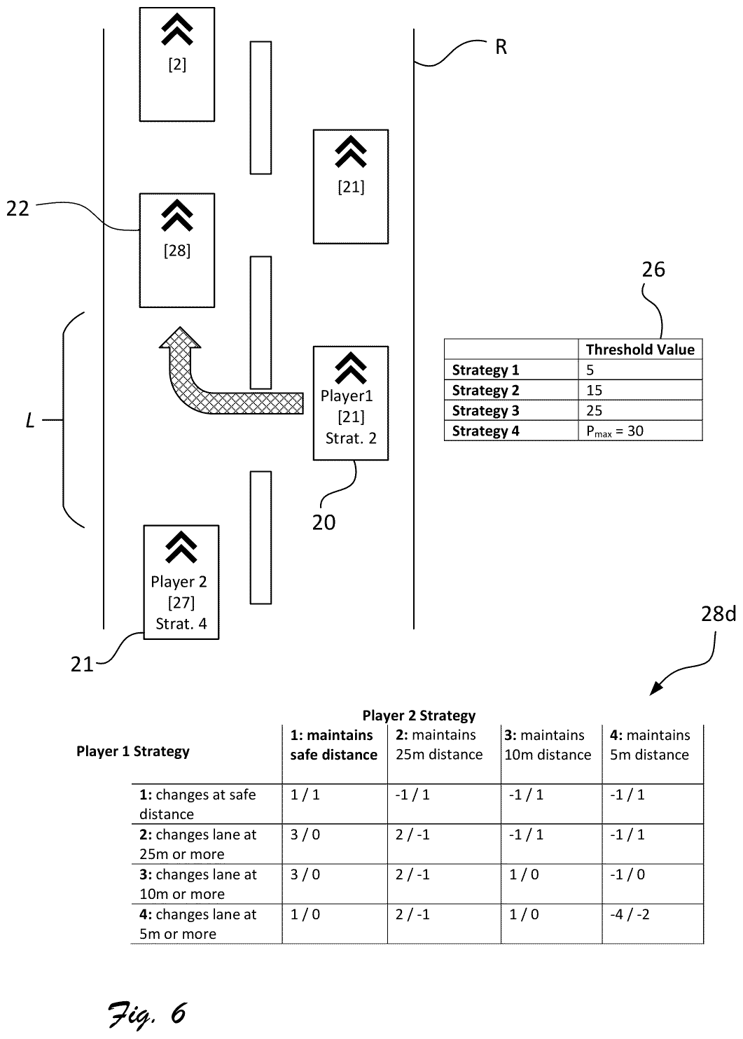

As a third example of a game situation, the illustration in FIG. 6 shows a merging situation, in which the first road user 20 seeks to change to a lane in which the second road user 21 is traveling. The virtual test environment recognizes the traffic situation as a “merging game” game situation, and designates the first road user 20 as the first player and the second road user 21 as the second player. The predefined parameter constellation on the basis of which the virtual test environment 1 recognizes a traffic situation as a merging game is: the second road user 21 is one lane further to the left than the first road user 20; the first road user 20 and the second road user 21 are traveling in the same direction on the road R; the first road user 20 is further ahead in the direction of travel than the second road user 21; the distance of the first road user 20 from the second road user 21 is below a threshold value, for example 150m; a third road user 22 is driving ahead of the second road user 21 in the same lane as the second road user 21; and the third road user 22 is behind the first road user 21.

The game commences in that the second player 21 drives up behind the third road user 22 to within a distance L whose magnitude depends on his strategy, or in other words leaves open a gap of length L behind the preceding vehicle into which the first player 20 can attempt to merge. The selection of strategies includes four strategies for each player, one cooperative and three aggressive for each. The cooperative strategy (strategy 1) of the first player 20 includes in only merging into the gap between the first player 21 and the third road user 22 if the distance L corresponds to at least the safe distance S of the second player 21 from the third road user 22. With an aggressive strategy, the first player 20 merges when the distance L is 25 m or more (strategy 2), 10 m or more (strategy 3), or 5 m or more (strategy 4). The cooperative strategy (strategy 1) of the second player 21 includes in maintaining the safe distance from the third road user 22 in order to allow the first player to safely merge into the gap. With an aggressive strategy, the second player drives up to within 25 m (strategy 2), 10 m (strategy 3), or 5 m of the third road user 22 in order to prevent the first player 20 from merging into the gap.

The balance in the first point account of the first player 20 is twenty-one points. The virtual test environment 1 therefore assigns the first player 20 the strategy 2 as the first strategy. The balance of the second point account of the second player 21 is twenty-seven points. The virtual test environment 1 therefore assigns the second player 21 the strategy 4. In accordance with the assigned strategies, the virtual test environment controls the second player 21 in such a manner that he drives up to within 5 m of the third road user 22, and controls the first player 20 in such a manner that he refrains from the lane change, since the distance L is less than 25 m. The virtual test environment consults a fourth payoff matrix 28d assigned to the merging game, deducts the first player 20 one point from the first point account, credits the second player 21 one point to the second point account, and concludes the game situation.

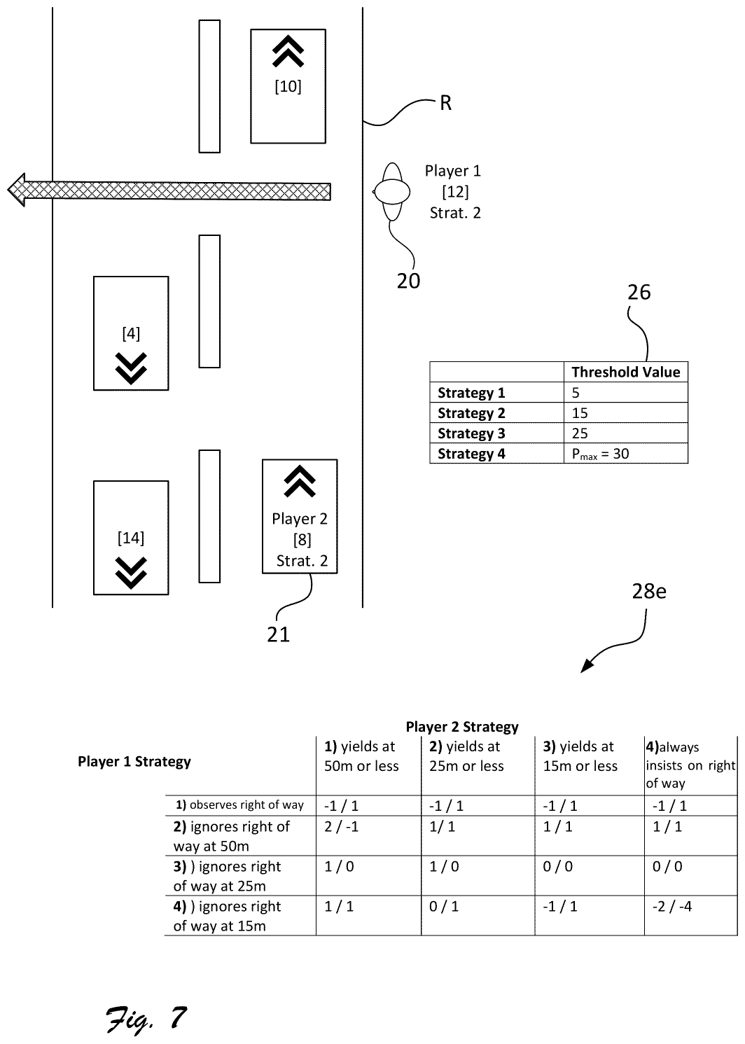

The illustration in FIG. 7 shows a crossing situation as a fourth example of a game situation, in which the first road user 20, a pedestrian by way of example, seeks to cross a road R in which the second road user 21, who has right of way over the first road user 20, is traveling. The virtual test environment recognizes the traffic situation as a “crossing game” game situation. The crossing game differs from the right-of-way game in FIG. 5 solely by the fact that the first road user 20 seeks to cross, rather than turn into, the lane in which the second road user 21 is traveling. The strategies that are available to the first player and the second player, respectively, are defined analogously to the strategies in the right-of-way game, and the parameter constellation on the basis of which the virtual test environment 1 recognizes a traffic situation as a crossing game is identical to the parameter constellation for the right-of-way game, apart from the fact that the goal of the first road user 20 is either the other side of the road or a lane branching off the road R on the opposite side of the road.

The point balance in the first point account of the first player 20 is twelve points. The virtual test environment 1 therefore assigns the first player 20 the strategy 2 as the first strategy. The point balance of the second point account of the second player 21 is eight points. The virtual test environment 1 therefore likewise assigns the second player 21 the strategy 2 as the second strategy. The virtual test environment controls the first player 20 and the second player 21 in such a manner that the first player crosses the road R as soon as the second player 21 has approached 50 m from the first player, and the second player 21 maintains his speed, which is to say does not allow the first player 20 to go. The virtual test environment consults a fifth payoff matrix 28e assigned to the crossing game, credits the first player 20 one point to the first point account, credits the second player one point to the second point account, and concludes the game situation.

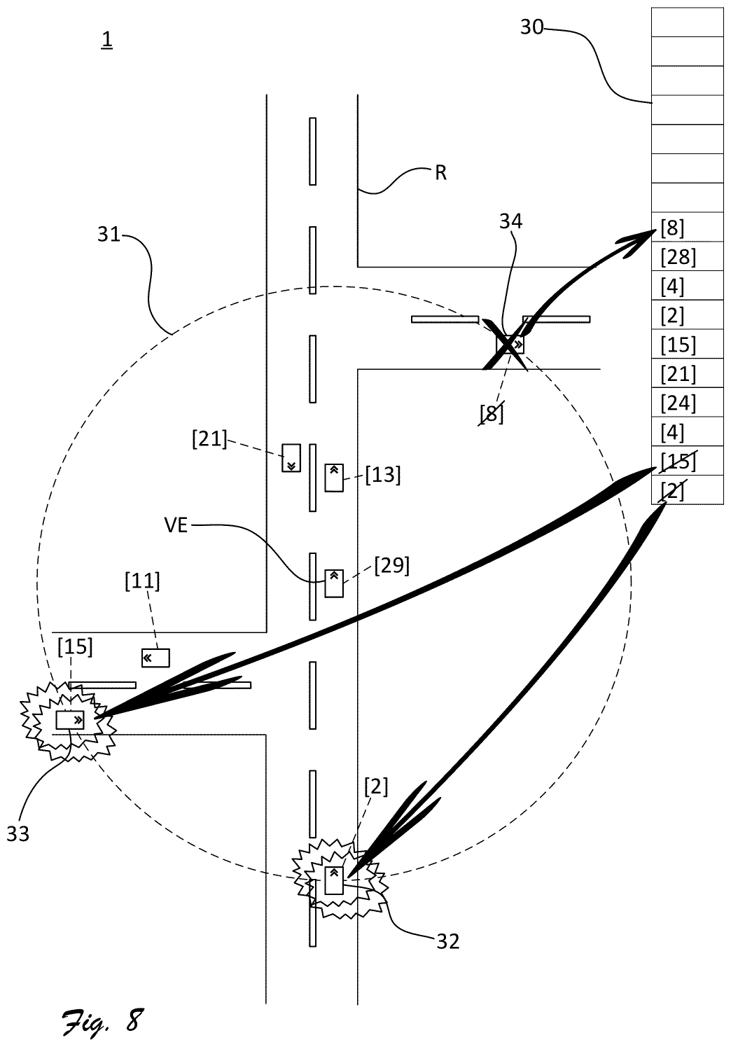

The illustration in FIG. 8 outlines an example of the virtual test environment 1 in which a mobile reference environment 31 of the virtual test vehicle VE is defined. The mobile reference environment 31 travels along with the virtual test vehicle VE in such a manner that the position of the virtual test vehicle VE remains unchanged within the mobile reference environment 21.

It can be seen in the illustration that the virtual test environment 1 is populated with virtual road users solely within the boundaries of the mobile reference environment 31. This measure serves to reduce the computational effort for simulation of the virtual test environment 1. The virtual test environment 1 is designed to add and to remove virtual road users at the boundaries of the mobile reference environment 31 of the virtual test environment 1. Shown in the illustration is how a fourth road user 32 and a fifth road user 33 are newly generated, which is to say added to the virtual test environment 1, at a boundary of the mobile reference environment 31, in order to subsequently travel into the mobile reference environment 31. While leaving the mobile reference environment 31, a sixth road user 34 has reached its boundaries and is removed from the virtual test environment 1.

The dimensions of the mobile reference environment 31 are significantly smaller than the dimensions of the (only partially depicted) virtual test environment 1, but preferably are sufficiently large to conceal the addition and removal of virtual road users at the boundaries of the mobile reference environment 31 from the driver assistance system 6. If a sensor field of view FV with limited range is assigned to the virtual test vehicle VE, then the dimensions of the mobile reference environment 31 preferably are chosen such that the mobile reference environment 31 completely surrounds the sensor field of view FV. In this way, the illusion of traveling in a richly populated test environment is conveyed to the driver assistance system 6 in a resource-saving manner.

The virtual test environment 1 includes a virtual memory 30 designed as a FIFO for storing point accounts of road users after their removal from the virtual test environment 1. On every removal of a road user, the virtual test environment 1 writes the balance of the point account of the respective removed road user to the highest position in the memory 30. By way of example in the illustration, the point account balance of eight points of the sixth road user 34 is transferred into the memory 30 at the highest point. On every addition of a new virtual road user, the virtual test environment 1 assigns a new point account to the respective newly added road user, transfers the point account balance stored in the lowest position of the memory 30 to the point account of the newly added road user, and then removes the transferred point account balance from the memory 30. By way of example in the illustration, a point account balance of two points stored in the memory 30 is transferred to the point account of the fourth road user 32, and a point account balance of fifteen points is transferred to the point account of the fifth road user 33. Both point account balances are then deleted from the memory 30. A point account balance of four points now stands at the lowest position of the memory 30 for the purpose of being transferred to the point account of the next newly generated road user. Preferably, the number of point accounts stored in the virtual test environment 1 altogether is sufficiently large to be able to allocate a point account to every virtual road user at any point in time.

In other words, upon addition to the virtual test environment, each virtual road user thus inherits an old point account from another virtual road user previously removed from the virtual test environment. Despite the constant removal and addition of road users in the virtual test environment, in this way the virtual test vehicle VE faces a constant number of potential players corresponding to the number of point accounts present altogether in the virtual test environment. Each of the road users removed from the virtual test environment 1 is indeed lost in its capacity as a controlling agent, but is retained in full in its capacity as a potential player, so that an equilibrium of different strategies can develop.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A virtual test environment for a driver assistance system that includes a virtual road and a plurality of virtual road users, the virtual test environment comprising:
a point account assigned to each road user of the plurality of virtual road users, the virtual test environment recognizing as a game situation at least one predetermined traffic situation in the virtual test environment in which a first road user with a first point account and a second road user with a second point account are involved, to designate the first road user as a first player in the game situation, and to designate the second road user as a second player in the game situation; and
a payoff matrix that is assigned to the game situation is stored in the virtual test environment;
wherein the virtual test environment assigns the first player in the game situation a first strategy from a selection of strategies for a behavior in the game situation depending on the balance of the first point account, and assigns the second player in the game situation a second strategy from the selection of strategies depending on the balance of the second point account,
wherein the virtual test environment controls the first player in such a manner that the first player behaves in accordance with the first strategy in the game situation, and controls the second player in such a manner that the second player behaves in accordance with the second strategy in the game situation,
wherein the virtual test environment applies a first payoff value stored in the payoff matrix and dependent on the course of the game situation to the first point account, and applies a second payoff value stored in the payoff matrix and dependent on the course of the game situation to the second point account,
wherein, in addition to the plurality of virtual road users, the virtual test environment comprises a virtual test vehicle and a logical interface for control of the virtual test vehicle by a driver assistance system, and
wherein the virtual test environment includes a programming interface for changing the payoff matrix or for changing at least one adjustment value for the point accounts that influences the assignment of the first strategy and the second strategy, so that a degree of difficulty of the virtual test environment for the driver assistance system is influenced via the programming interface by influencing the assignment of strategies.

2. The virtual test environment according to claim 1, wherein the traffic situation is:
a turning situation, in which the first road user seeks to turn into a road on which the second road user, who has right of way over the first road user, is traveling;
a merging situation, in which the first road user seeks to change to a lane being used by the second road user;
a car-following situation, in which the first road user is driving behind the second road user in a lane and seeks to pass the second road user; and/or
a crossing situation, in which the first road user seeks to cross a road on which the second road user, who has right of way over the first road user, is traveling.

3. The virtual test environment according to claim 1, wherein the first payoff value is dependent on the first strategy and the second strategy in the game situation, and the second payoff value is dependent on the first strategy and the second strategy in the game situation.

4. The virtual test environment according to claim 1, wherein the selection of strategies includes at least one aggressive strategy and at least one cooperative strategy.

5. The virtual test environment according to claim 4, wherein the virtual test environment is designed to read in a user-defined value at the programming interface and to derive a target proportion of aggressive road users in the virtual test environment from the user-defined value, and includes a regulating algorithm that is designed to adjust the probability that an aggressive strategy is assigned to the first player or the second player to the target proportion via an iterative change in the payoff matrix or the adjustment value.

6. The virtual test environment according to claim 1, wherein:
the virtual test environment is designed to define a mobile reference environment of the virtual test vehicle whose dimensions are smaller than the dimensions of the virtual test environment, and to add virtual road users and to remove virtual road users at the boundaries of the mobile reference environment of the virtual test environment; and
the virtual test environment is designed to store the balance of the point account of a removed virtual road user when removing the virtual road user and, when adding a virtual road user, to transfer the stored balance of the point account to the point account of the added virtual road user.

7. The virtual test environment according to claim 1, wherein the virtual test environment is:
designed to withdraw the status of first player from the first road user and to withdraw the status of second player from the second road user after a conclusion of the game situation;
to control the first road user, after withdrawing the status of first player, in such a manner that the behavior of the first road user in the virtual test environment is dependent on the balance of the first point account; and
to control the second road user, after withdrawing the status of second player, in such a manner that the behavior of the second road user in the virtual test environment is dependent on the balance of the second point account.

8. A computer-implemented method for testing a driver assistance system in a virtual test environment that comprises a virtual road network and a plurality of virtual road users, the method comprising:
assigning a point account to each road user from the multiplicity of road users;
recognizing, in the virtual test environment, as a game situation, at least one predetermined traffic situation in which a first road user with a first point account and a second road user with a second point account are involved;
designating the first road user as a first player in the game situation;
designating the second road user as a second player in the game situation;
assigning a first strategy from a selection of strategies for a behavior in the game situation to the first player as a function of the balance of the first point account, wherein the selection of strategies includes at least one aggressive strategy and at least one cooperative strategy;
assigning a second strategy from the selection of strategies to the second player as a function of the balance of the second point account;
controlling the first player in such a manner that the first player behaves in accordance with the first strategy in the game situation;
controlling the second player in such a manner that the second player behaves in accordance with the second strategy in the game situation;
analyzing the course of the game situation;
applying to the first point account a first payoff value that is dependent on the course of the game situation and is stored in a payoff matrix assigned to the game situation;
applying to the second point account a second payoff value that is dependent on the course of the game situation and is stored in the payoff matrix;
providing a configuration of the driver assistance system to control a virtual test vehicle in the virtual test environment;
providing a configuration of the virtual test environment to feed synthetic sensor data into at least one sensor data input of the driver assistance system;
providing a performance of a first test drive of the driver assistance system in the virtual test environment;
increasing a degree of difficulty of the virtual test environment after conclusion of the first test drive by changing the payoff matrix or an adjustment value for the point accounts that influences the assignment of the first strategy and the second strategy in such a manner that the probability that an aggressive strategy is assigned to the first player or the second player is increased after the change; and
performing a second test drive of the driver assistance system in the virtual test environment after increasing the degree of difficulty.

9. The method according to claim 7, wherein the increasing of the degree of difficulty includes:
regulating the probability that an aggressive strategy is assigned to the first player in the game situation to a target proportion of aggressive road users in the virtual test environment via an iterative change in the payoff matrix or the adjustment value.
